(19) United States
(12) Patent Application Publication
(10) Pub. No.: US 2011/0082652 A1
(43) Pub. Date: Apr. 7, 2011

(54) Method and Apparatus for Fault Detection

(76) Inventor: Bahram Honary, Lancaster (GB)

(21) Appl. No.: 12/992,066

(22) PCT Filed: Jul. 3, 2009
(86) PCT No.: PCT/GB2009/001674

§ 371 Date: Nov. 10, 2010

(30) Foreign Application Priority Data
Jul. 4, 2008 (GB) 0812253.3

(51) Int. Cl. G01R 31/02

(52) U.S. Cl. 702/58; 324/537

(57) ABSTRACT

A method for fault detection in a signal carrying component. The method comprises applying a first input signal to a first part of the signal carrying component, and applying a second input signal to the signal carrying component. A resultant signal is obtained from the signal carrying component, the resultant signal resulting from interactions of the first and second input signals in the signal carrying component. The resultant signal is processed to determine whether a fault exists in the signal carrying component, the processing being based upon identification of intermodulation products created by the first and second input signals in the signal carrying component. At least one of the first and second input signals is wirelessly injected to the signal carrying component and/or the resultant signal is wirelessly obtained from the signal carrying component.

The present invention relates to a method and apparatus for use in fault detection. More particularly, but not exclusively, the invention relates to a method and apparatus for use in detecting faults in wires and cables.

In the modern world, a large number of devices involve ever increasing electrical and electronic complexity. In particular, many larger devices now include large numbers of wires electronically connecting components of the device. This is particularly the case in vehicles such as aircraft and road vehicles, but is also true for various items of industrial machinery which comprise complex electronic control systems.

Wires and cables, necessarily, have lifetime limitations due to material degradation and the operating conditions to which they are exposed (e.g. vibrations in many cases as well as chemical, thermal, electrical and mechanical stresses). Aging wiring can result in degraded system performance and it is therefore desirable to identify faults in wiring systems, preferably before such faults reach a stage at which system performance is unacceptably degraded.

Various techniques have therefore been proposed to identify faults in wires and cables. One such technique involves connecting each end of a wire to a test system so as to determine whether the wire exhibits a fault condition. While such techniques are effective in identifying faults, they require that each end of the wire is electrically connected to the test system for fault identification. This can be problematic where the wire of interest is not easily accessible. This is often the case in wiring systems of complexes devices such as vehicles.

It is an object of embodiments of the invention to obviate or mitigate at least some of the problems set out above.

According to a first aspect of the invention, there is provided a method for fault detection in a signal carrying component. The method comprises applying a first input signal to a first part of said signal carrying component; applying a second input signal to said signal carrying component; obtaining a resultant signal from the signal carrying component, said resultant signal resulting from interactions of said first and second input signals in said signal carrying component; and processing the resultant signal to determine whether a fault exists in said signal carrying component, said processing being based upon identification of intermodulation products created by said first and second input signals in said signal carrying component; wherein at least one of the first and second input signals is wirelessly injected to said signal carrying component and/or said resultant signal is wirelessly obtained from said signal carrying component.

In this way, the invention provides a method of fault detection in which signals are applied to a signal carrying component (e.g. a substantially linear structure such as a cable or wire) and a resultant signal is analysed to determine whether a fault exists. The analysis is based upon the presence of intermodulation products in the resultant signal. As indicated, at least one of the first and second signals is wirelessly applied and/or the resultant signal is wirelessly obtained. In this way, it will be appreciated that there is no need for a wired connection to the signal carrying component that is to be tested. This is particularly beneficial where the signal carrying component is not easily accessible (e.g. where it is embedded within a complex device such as a vehicle).

The fault to be detected may be a non-linear fault. The resultant signal may be analysed to detect fault conditions, particularly non-linear fault conditions resulting in intermodulation products being present in the resultant signal.

The second input signal may be applied to a second part of the signal carrying component other than the first part of the signal carrying. The resultant signal may be obtained from one of the first and second part of the signal carrying component. The second input signal may be wirelessly applied to the signal carrying component.

The first input signal may have a first frequency and the second input signal may have a second, different frequency. Each of said first and second frequencies may be a frequency of more than 1 GHz.

The first input signal may be generated by modulating a first initial signal with a first sequence of values. The second input signal may be generated by modulating a second initial signal with a second sequence of values. The first and second sequences of values may be the same or different. Each of said first and second sequences of values may be random or pseudo-random sequences of values.

At least one of the first and second input signals may be applied to the signal carrying component by conduction. The resultant signal may be obtained by conduction from the signal carrying component. That is signals may be applied or obtained from the signal carrying component by a wired connection to a suitable part of the signal carrying component.

One of said first and second input signals may be applied into said signal carrying component using a transceiver, and the transceiver may be used to obtain the resultant signal. The first and second input signals may be applied using respective transceivers, the first transceiver applying said first input signal and obtaining said resultant signal, and the second transceiver applying said second input signal and obtaining a fourth signal from the signal carrying component. One of the transceivers may apply and obtain signals by a wired connection to the signal carrying component (e.g a connection by conduction). At least one of the transceivers may be a wireless transceiver. At least one of the transceivers may be an ultra-wide-band (UWB) transceiver.

The method may further comprise obtaining a first resultant signal at a first time, and a second resultant signal at a second time, and monitoring a state of the signal carrying component over time using said first resultant signal and said second resultant signal.

Processing the resultant signal to determine whether a fault exists in said signal carrying component may comprise processing said resultant signal together with reference data. The reference data may be formed from said first input signal. For example, the reference data may be based upon an auto-correlation of said first input signal. The reference data may be formed from said first and second input signals.

For example, the reference data may be based upon a cross-correlation of said first and second input signals.

According to a second aspect of the present invention, there is provided an apparatus for detecting faults in a signal carrying component. The apparatus comprises a first transmitter for applying a first input signal at a first part of said signal carrying component; a second transmitter for applying a second input signal to the signal carrying component; a receiver for obtaining a resultant signal from the signal carrying component, the resultant signal resulting from interactions of the first and second input signals in the signal carrying component; and a processor for processing the resultant signal to determine whether a fault exists in said signal carrying component, said processing being based upon identification of intermodulation products created by said first and second input signals in said signal carrying component. At least one of said first and second transmitters is arranged to wirelessly inject its signal to said signal carrying component and/or said receiver is arranged to wirelessly obtain said resultant signal from said signal carrying component.

Said receiver and said second transmitter may form a transceiver. Said first transmitter may be a transceiver arranged to apply said first input signal to the signal carrying component and obtain a signal from said first part of the signal carrying component.

It will be appreciated that the apparatus provided by the second aspect of the invention may be adapted to provide features described above in the context of the first aspect of the invention.

The invention also provides apparatus and method for detecting and diagnosing actual and developing faults in electrical wiring systems; the apparatus comprising a plurality of radio frequency signal generators and modulators, at least one portable wireless transceiver and at least one further wired and/or wireless transceiver (where the transceivers inject signals into the system under test), and a data processing system; and the method comprising analysing intermodulation products of the injected signals

The injected signal maybe an ultra wideband radio frequency signal. The injected signal may be modulated by a pseudo random sequence. The methods and apparatus may be configured to operate where the wiring system is in situ in a land vehicle, a water vehicle, an aerospace vehicle, a building, an industrial plant, and/or underground. The method may comprise using the apparatus on a test system on a plurality of occasions and diagnosing the condition via differences in output signals. The method may alternatively comprise using the apparatus on a single occasion and diagnosing condition via reference to modelled behaviour. The method may also comprise classifying the state of a wire based on the number, severity and/or class of faults detected.

Apparatus provided by the invention may be implemented in any convenient form, including by way of suitable data processing systems, firmware and/or software. The invention may also be implemented using a field programmable data array (FPGA) and/or an electronic computer.

Embodiments of the invention are now described with reference to the accompanying drawings in which:

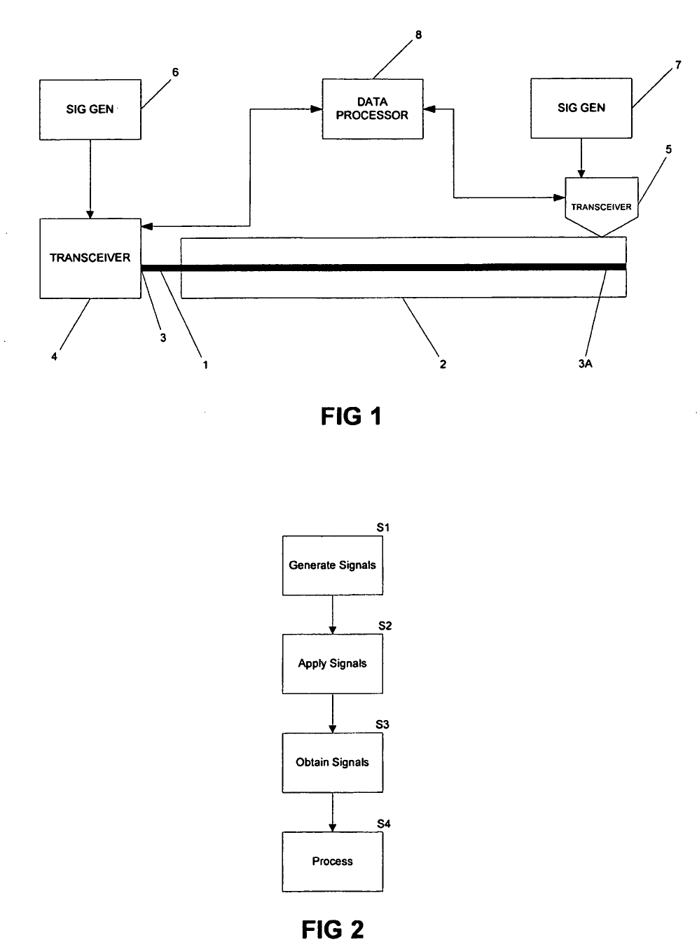

FIG. 1 is a schematic illustration of a wire to be tested for faults;

FIG. 2 is a flowchart of processing carried out in an embodiment of the invention;

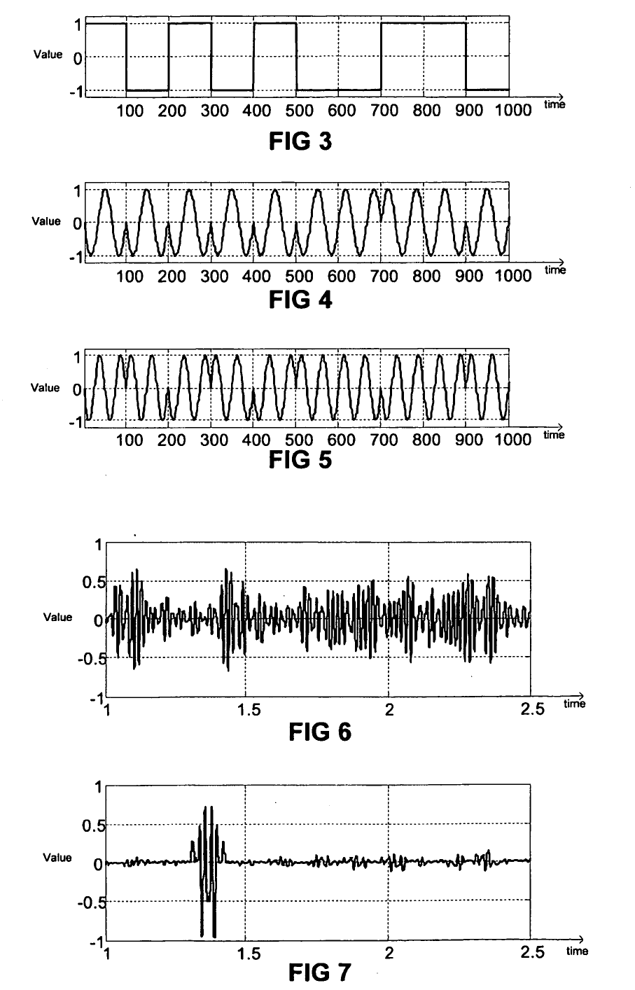

FIG. 3 is an illustration of part of a binary sequence;

FIG. 4 is an illustration of a first signal initial after modulation using the binary sequence of FIG. 3;

FIG. 5 is an illustration of a second initial signal after modulation using the binary sequence of FIG. 3;

FIG. 6 is a an illustration of the cross-correlation of the signal of FIG. 4 and the signal of FIG. 5; and

FIG. 7 is an illustration showing interactions between the signal of FIG. 4 and the signal of FIG. 5 in the presence of a non-linear fault.

Referring to FIG. 1, a wire 1 is illustrated. The wire 1 is housed within a housing 2. A first end 3 of the wire 1 is accessible at an end of the housing, but much of the wire is completely encased within the housing 2. It is desired to test the wire 1 to determine whether it exhibits any fault conditions. In order to carry out such testing, the first end 3 of the wire 1 is connected (by wired means) to a transceiver 4. A wireless transceiver 5 is applied proximate another end 3A of the wire 1, the other end 3A of the wire being inaccessible for connection by wired means.

The wireless transceiver 5 is arranged to apply a signal to the wire 1, and receive a signal from the wire 1 using radio frequency signals. In a particular embodiment the wireless transceiver 5 is an ultra-wide band transceiver, and the signals applied may have frequencies greater than 1 GHz. The power of the wireless transceiver may be of the order of 100 microwatts.

The transceiver 4 applies a first signal to the wire, the first signal being generated by a first signal generator 6. The transceiver 5 applies a second signal to the wire, the second signal being generated by a second signal generator 7. Each of the signal generators 6, 7 may be controlled by a single controller (not shown) so as to synchronise their operation.

Each of the transceivers 4, 5 also receives a signal from the wire 1. In the case of the transceiver 4, the signal is received by wired means, while in the case of the transceiver 5 the signal is received by wireless means. Each of the transceivers 4, 5 is also connected to a data processor 8 which is arranged to process signals received by the transceivers from the wire 1, together with the signals applied to the wire by the transceivers 4, 5.

In order to determine whether the wire 1 exhibits a fault condition, processing is carried out as is now described with reference to FIG. 2.

At step S1, a first signal is generated by the first signal generator 6. The first signal generator 6 is arranged to modulate a sine wave of particular frequency using a pseudo-random binary sequence. An example of part of a suitable pseudo-random binary sequence is shown in FIG. 3. The first signal generated by the first signal generator 6 by this modulation is shown in FIG. 4.

The second signal generator 7 is arranged to modulate a sine wave of a different frequency to that used by the first signal generator 6. The modulation may be based upon the same pseudo random sequence used by the first signal generator 6, or alternatively may be based upon a different sequence. FIG. 5 shows the second signal generated by the second signal generator 7 by modulating a sine wave of different frequency to that used by the first signal generator 6 with the pseudo-random sequence shown in FIG. 3.

Signals generated at step S1 are applied to the wire 1 by wired and wireless means at step S2, as described above. At step S3 each of the transceivers obtains a signal from the wire 2. The signals obtained are processed to provide a determination as to whether the wire 1 exhibits characteristics which are indicative of a fault condition.

If the wire has good integrity, it would be expected that the first signal applied by the transceiver 4 and the second signal applied by the transceiver 5 would not interact in the wire other than to sum. That is, it would be expected that the signals obtained from the wire by each of the transceivers would be the cross-correlation of the first and second signals. The cross-correlation of the first and second signals (shown in FIGS. 4 and 5 respectively) is shown in FIG. 6.

The inventors have realised, however, that if a non-linear fault is present in the wire 1, the first and second signals will interact to form intermodulation products. Such intermodulation products are formed by a variety of non-linearities in the wire 1. For example, such products may be formed as a result of corrosion in the wire 1 causing part of the wire to act as a non-linear junction. A variety of intermodulation products will be produced by a non-linear fault. More particularly, where the first signal has a frequency f₁ and the second signal has a frequency f₂ a plurality of intermodulation products having respective frequencies will be generated according to equation (1):

fₛ=±Mf₁±Nf₂ (1)

where fₛ is the frequency caused by the non-linearity;

M and N are each positive integers, each intermodulation product has an ‘order’ given by M+N.

FIG. 7 shows the cross correlation of one of the signals applied by one of the transceivers 4, 5 with a signal obtained by one of the transceivers 4, 5 when the wire 1 has a non-linear fault. The waveform of FIG. 7 can be analysed by identifying the most dominant peaks (i.e. the peaks with the greatest amplitude), and determining whether there are a small number of peaks which have an amplitude which is considerably greater than that of all other peaks in the signal. Where such peaks are identified it is determined that they are the result of an intermodulation product created by a non-linear fault.

Different types of faults may be classified based upon, for example, the absolute and relative amplitudes of peaks within the signal. Additionally, consideration may be given to the presence of harmonics of the dominant peaks.

The location of a non-linear fault can be determined from the signal of FIG. 7 using a time average of the two dominant peaks. More particularly, this time average can be converted into a distance between the end of the wire 1 and the location of the fault.

Although it has been described above that the transceiver 4 is a wired transceiver, it will be appreciated that in alternative embodiments of the invention, the transceiver 4 may be a wireless transceiver of a similar form to the wireless transceiver 5 described above.

In an alternative embodiment of the invention, each of the transceivers 4, 5 applies a respective signal to the wire 1, but only the transceiver 4 receives a signal from the wire 1. That is, the determination of a fault is based upon a comparison between the cross-correlation of the signal applied by the transceivers 4, 5 and the signal received by the transceiver 4. It will be appreciated that a similar arrangement can be achieved whereby only the transceiver 5 receives a signal from the wire 1.

It will be appreciated that in some of the embodiments described above one or both of the transceivers 4, 5, can be replaced by a transmitter or receiver.

The methods described above can be applied in a variety of different ways. For example, regular testing in the manner set out above will allow signals obtained from the wire at different times to be compared with one another thereby allowing changes in the integrity of the wire 1 over time to be monitored. This can be particularly valuable as changes can be detected before they cause a fault condition to occur in operation, thereby allowing operational faults to be pre-emptively identified.

It has been explained that the transceiver 5 is a wireless transceiver, such a ultra-wide band radio transceiver. The transceiver 5 can apply a signal to the wire 1 either by using an antennae or alternatively by using a “clamp” which surrounds to outer surface of the wire to apply and receive signals. While the use of such a clamp may provide better results in some circumstances, the use of an antennae is sometimes beneficial where a wire is inaccessible to the extent that a clamp cannot be located around the outer surface of the wire.

It will be appreciated that various modifications can be made to the described embodiments without departing from the spirit and scope of the present invention.

1. A method for fault detection in a signal carrying component, the method comprising:
applying a first input signal to a first part of said signal carrying component;
applying a second input signal to said signal carrying component;
obtaining a resultant signal from the signal carrying component, said resultant signal resulting from interactions of said first and second input signals in said signal carrying component;
processing the resultant signal to determine whether a fault exists in said signal carrying component, said processing being based upon identification of intermodulation products created by said first and second input signals in said signal carrying component;
wherein at least one of the first and second input signals is wirelessly injected to said signal carrying component and/or said resultant signal is wirelessly obtained from said signal carrying component.

2. A method according to claim 1, wherein said signal carrying component is a substantially linear structure.

3. A method according to claim 1 or 2 wherein the signal carrying component is a cable.

4. A method according to any preceding claim, wherein said fault is a non-linear fault.

5. A method according to any preceding claim, wherein said second input signal is applied to a second part of said signal carrying component other than said first part of said signal carrying component.

6. A method according to claim 5, wherein said resultant signal is obtained from one of said first and second parts of said signal carrying component.

7. A method according to any preceding claim wherein said second input signal is wirelessly applied to said signal carrying component.

8. A method according to any preceding claim, wherein said first input signal has a first frequency and said second input signal has a second, different frequency.

9. A method according to claim 8, wherein each of said first and second frequencies is a frequency of more than 1 GHz.

10. A method according to any preceding claim, further comprising:
modulating a first initial signal with a first sequence of values to generate said first signal; and
modulating a second initial signal with a second sequence of values to generate said second signal.

11. A method according to claim 10, wherein one or both of said first and second sequences of values are respective random or pseudo-random sequences of values.

12. A method according to any preceding claim, wherein at least one of the first and second input signals is applied to the signal carrying component by conduction.

13. A method according to any preceding claim, wherein said resultant signal is obtained from the signal carrying component by conduction.

14. A method according to any preceding claim, wherein one of said first and second input signals is injected into said signal carrying component using a transceiver, and the transceiver is used to obtain the resultant signal.

15. A method according to any preceding claim, wherein said first and second input signals are injected using respective transceivers, the first transceiver injecting said first input signal and obtaining said resultant signal, and said second transceiver injecting said second signal and obtaining a further resultant signal from the signal carrying component.

16. A method according to claim 15, wherein one of the transceivers injects and obtains signals by a wired connection to the signal carrying component.

17. A method according to claim 15 or 16, wherein at least one of the transceivers is a wireless transceiver.

18. A method according to claim 17, wherein at least one of the transceivers is an ultra-wide-band (UWB) transceiver.

19. A method according to any preceding claim, further comprising:
obtaining a first resultant signal at a first time, and a second resultant signal at a second time, and monitoring a state of the signal carrying component over time using said first resultant signal and said second resultant signal.

20. A method according to any preceding claim, wherein processing the resultant signal to determine whether a fault exists in said signal carrying component comprises processing said third signal together with reference data.

21. A method according to claim 20, wherein said reference data is formed from said first input signal.

22. A method according to claim 21, wherein said reference data is based upon an auto-correlation of said first input signal.

23. A method according to claim 20, wherein said reference data is formed from said first and second input signals.

24. A method according to claim 23, wherein said reference data is based upon a cross-correlation of said first and second input signals.

25. Apparatus for detecting faults in a signal carrying component, the apparatus comprising:
a first transmitter for applying a first input signal at a first part of said signal carrying component;
a second transmitter for applying a second input signal to said signal carrying component;
a receiver for obtaining a resultant signal from the signal carrying component, said resultant signal resulting from interactions of said first and second input signals in said signal carrying component; and
a processor for processing the resultant signal to determine whether a fault exists in said signal carrying component, said processing being based upon identification of intermodulation products created by said first and second input signals in said signal carrying component;
wherein at least one of said first and second transmitters is arranged to wirelessly inject its signal to said signal carrying component and/or said receiver is arranged to wirelessly obtain said resultant signal from said signal carrying component.

26. Apparatus according to claim 25, wherein said receiver and said second transmitter form a transceiver.

27. Apparatus according to claim 25, wherein said first transmitter is a transceiver arranged to apply said first signal to the signal carrying component and obtain a signal from said first part of the signal carrying component.
